(19) United States
(12) Patent Application Publication
(10) Pub. No.: US 2026/0206501 A1
(43) Pub. Date: Jul. 16, 2026

(54) SEMICONDUCTOR DEVICE AND MANUFACTURING METHOD THEREFOR

(71) Applicant: JUSUNG ENGINEERING CO., LTD., Gwangju-Si, Gyeonggi-Do (KR)

(72) Inventors: Won Tae CHO, Gwangju-Si, Gyeonggi-Do (KR); Chul Joo HWANG, Gwangju-Si, Gyeonggi-Do (KR)

(21) Appl. No.: 19/135,022

(22) PCT Filed: Nov. 27, 2023
(86) PCT No.: PCT/KR2023/019241

§ 371 Date: Jun. 2, 2025

(30) Foreign Application Priority Data
Dec. 1, 2022 (KR) 10-2022-0165542
May 9, 2023 (KR) 10-2023-0060082

(51) Int. Cl. H10P 14/20; C03C 17/34; C23C 16/34; C23C 16/40; C23C 16/455; H10D 30/67; H10P 14/24

(52) U.S. Cl. CPC H10P 14/3226; C03C 17/3435; C23C 16/34; C23C 16/407; C23C 16/45536; H10D 30/675; H10D 30/6757; H10P 14/24; H10P 14/2922; H10P 14/3416; C03C 2218/153

(57) ABSTRACT

Provided are a semiconductor device and a method for manufacturing the same, and more specifically, to a method for manufacturing a semiconductor device including a semiconductor layer containing gallium nitride. A semiconductor device includes a glass substrate, a seed layer disposed on the glass substrate, and a semiconductor layer containing gallium nitride and disposed on the seed layer.

### TECHNICAL FIELD

The present disclosure relates to a semiconductor device and a method for manufacturing the same, and more specifically, to a method for manufacturing a semiconductor device including a semiconductor layer containing gallium nitride.

### BACKGROUND ART

Thin film transistors are used as switching circuits in semiconductor apparatuses and display devices. An active layer of such a thin film transistor provides a channel region between a gate electrode, a source electrode, and a drain electrode.

In the related art, amorphous or crystalline silicon have been used as the active layer of the thin film transistor. However, when silicon is used as the active layer, there are disadvantages such as a relatively slow reaction speed and a relatively high power loss. Thus, research is being actively conducted to use gallium nitride, which enables fast signal conversion and has a low energy loss rate, as the active layer in the thin film transistor.

To form the gallium nitride thin film, a metal organic chemical vapor deposition (MOCVD) method is generally used. In the organic metal chemical vapor deposition method, the gallium nitride thin film is deposited at a temperature of approximately 1,000° C. or more. That is, when the substrate is maintained at a high temperature of approximately 1,000° C. or more, a crystallized gallium nitride thin film may be deposited on the substrate.

However, if the gallium nitride thin film is formed in the state in which the substrate is heated to the high temperature, a limitation in which a substrate or a thin film formed on the substrate is damaged occurs. Particularly, glass substrates are damaged at a temperature above approximately 600° C., and thus, glass substrates, which have the advantage of being easy to enlarge and are inexpensive, may not be used to form the gallium nitride thin film, resulting in an excessive increase in manufacturing costs.

### RELATED ART DOCUMENT

(Patent Document 1) KR 10-2019-0074774 A

### DISCLOSURE OF THE INVENTION

### Technical Problem

The present disclosure provides a semiconductor device including gallium nitride crystallized at a low temperature and a method for manufacturing the same.

### Technical Solution

In accordance with an exemplary embodiment, a semiconductor device includes: a glass substrate; a seed layer disposed on the glass substrate; and a semiconductor layer containing gallium nitride and disposed on the seed layer.

The seed layer may have a hexagonal crystal structure.

The seed layer may include zinc oxide.

The seed layer may be formed through an atomic layer deposition process.

In accordance with another exemplary embodiment, a method for manufacturing a semiconductor device includes: preparing a glass substrate in a reaction space; forming a crystalline seed layer on the glass substrate; and forming a semiconductor layer containing gallium nitride on the seed layer.

The seed layer may contain zinc oxide, and in the forming of the seed layer, the seed layer may be formed on the glass substrate through an atomic layer deposition process.

In the forming of the semiconductor layer, the semiconductor layer may be formed on the seed layer through a chemical vapor deposition process or an atomic layer deposition process.

The forming of the semiconductor layer may include: forming a first semiconductor layer on the seed layer through an atomic layer deposition process; and forming a second semiconductor layer on the first semiconductor layer through a chemical vapor deposition process.

In the forming of the semiconductor layer, the semiconductor layer may be formed through an atomic layer deposition process in which a source gas containing gallium and a reactant gas containing nitrogen are sequentially supplied to the reaction space, and when the reactant gas is supplied, plasma may be formed in the reaction space.

In the forming of the semiconductor layer, the semiconductor layer may be formed through an atomic layer deposition process in which a source gas containing gallium and a reactant gas containing nitrogen are sequentially supplied to the reaction space, and before supplying the reactant gas after supplying the source gas, plasma may be formed in the reaction space.

In the forming of the seed layer and the forming of the semiconductor layer, a temperature of the reaction space may be maintained to a temperature of approximately 500° C. or less.

The method may further include exposing the semiconductor layer to hydrogen or oxygen plasma.

The method may further include, before the forming of the semiconductor layer, supplying a gas comprising at least one of fluorine or chlorine to the reaction space.

The forming of the seed layer and the forming of the semiconductor layer may be performed in the same chamber.

The forming of the seed layer and the forming of the semiconductor layer may be continuously performed in chambers different from each other.

In accordance with yet another exemplary embodiment, a thin film transistor includes: a gate electrode disposed on a glass substrate; a gate insulating layer disposed on the gate electrode; an active layer disposed on the gate insulating layer, comprising a crystalline seed layer and a semiconductor layer containing gallium nitride and disposed on the seed layer; and a source electrode and a drain electrode spaced apart from each other on the active layer.

In accordance with still another exemplary embodiment, a thin film transistor includes: a source electrode and a drain electrode spaced apart from each other on a glass substrate; an active layer extending on the source electrode and the drain electrode and comprising a crystalline seed layer and a semiconductor layer containing gallium nitride and disposed on the seed layer; a gate insulating layer disposed on the active layer; and a gate electrode disposed on the gate insulating layer.

The seed layer may have a hexagonal crystal structure.

The seed layer may include zinc oxide.

### Advantageous Effects

According to the exemplary embodiment, the semiconductor layer containing gallium nitride crystallized at the low temperature may be formed.

That is, in accordance with the embodiments of the present disclosure, the semiconductor layer may be formed on the crystalline seed layer to form the semiconductor layer containing gallium nitride crystallized at the low temperature of approximately 500° C. or less without damaging the glass substrate.

In addition, the semiconductor layer formed described above may be used as the active layer to manufacture the transistor that is enables the fast signal conversion and has the low energy loss rate.

### BRIEF DESCRIPTION OF THE DRAWINGS

FIG. 1 is a schematic view of an apparatus for processing a substrate in accordance with an exemplary embodiment;

FIG. 2 is a schematic view of a method for manufacturing a semiconductor device in accordance with an exemplary embodiment;

FIG. 3 is a view for explaining a process cycle in a process of forming a semiconductor layer in accordance with an exemplary embodiment;

FIG. 4 is a schematic view of a thin film transistor in accordance with an exemplary embodiment; and

FIG. 5 is a schematic view of a thin film transistor in accordance with another exemplary embodiment.

### MODE FOR CARRYING OUT THE INVENTION

Hereinafter, exemplary embodiments will be described in detail with reference to the accompanying drawings. The present invention may, however, be embodied in different forms and should not be construed as limited to the exemplary embodiments set forth herein. Rather, these embodiments are provided so that the present invention will be thorough and complete, and will fully convey the scope of the present invention to those skilled in the art.

It will also be understood that when a layer, a film, a region, or a substrate is referred to as being ‘on’ another one, it can be directly on the other one, or one or more intervening layers, films, regions, or substrates may also be present.

Also, spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. In the figures, the dimensions of layers and areas may be exaggerated for clarity of illustration. Like reference numerals refer to like elements throughout.

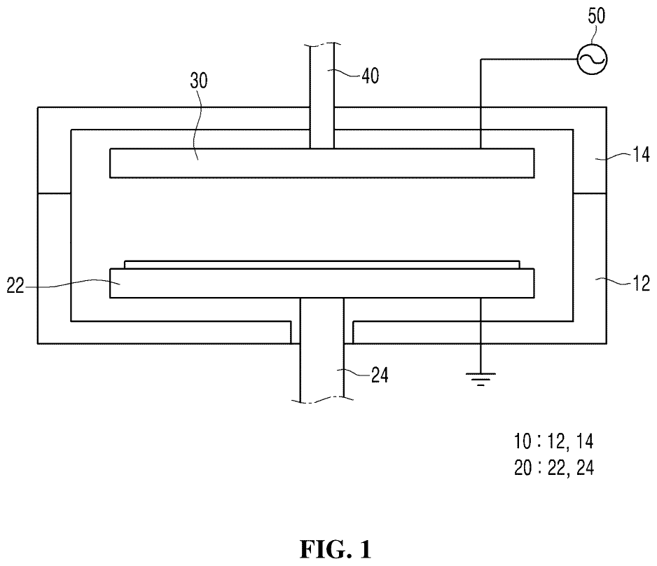

FIG. 1 is a schematic view of an apparatus for processing a substrate in accordance with an exemplary embodiment.

Referring to FIG. 1, an apparatus for processing a substrate in accordance with an exemplary may be an apparatus for depositing a thin film containing gallium nitride (GaN) and may include a chamber 10, a substrate support part prepared in the chamber 10 to support a substrate S provided in the chamber 10, a gas injection part 30 prepared in the chamber 10 to face the substrate support part 20 and configured to inject a process gas toward the substrate support part 20, and an RF power source 50 configured to supply power so as to generate plasma within the chamber 10. In addition, the apparatus for processing the substrate may include a gas supply part 40 that supplies the process gas, and may further include a controller (not shown) that controls the RF power source 50.

The chamber 10 provides a predetermined reaction space and is maintained to seal the reaction space. The chamber 10 may include a body 12 including an approximately circular or square-shape plane and a sidewall extending upward from the plane and having a predetermined reaction space and a cover 14 having an approximately circular or square shape and disposed on the body 12 to seal the chamber 10. However, the chamber 10 is not limited thereto and may be manufactured in various shapes corresponding to a shape of the substrate S.

An exhaust port (not shown) may be provided on a predetermined area of a bottom surface of the chamber 10, and an exhaust tube (not shown) connected to the exhaust port may be provided outside the chamber 10. Also, the exhaust tube may be connected to an exhaust device (not shown). A vacuum pump such as a turbo molecular pump may be used as the exhaust device. Therefore, the inside of the chamber may be vacuumized under a predetermined reduced pressure atmosphere, for example, to a predetermined pressure of approximately 0.1 mTorr or less by the exhaust device. The exhaust tube may be installed not only on the bottom surface of the chamber 10, but also on a side surface of the chamber 10 under the substrate support part 20 to be described later. In addition, a plurality of exhaust tubes and the exhaust device corresponding thereto may be further installed to reduce an exhaust time.

The substrate provided into the chamber 10, in which the thin film formation process is performed, is seated on the substrate support part 20. Here, the substrate S may include an amorphous substrate. In addition, the substrate S may include a glass substrate. The substrate S may have a seed layer already disposed on the substrate S or may be provided into the chamber 10 in the state in which the seed layer is not disposed. The substrate support part 20 may include an electrostatic chuck to adsorb and maintain the substrate S by using an electrostatic force so that the substrate S is seated and supported. Alternatively, the substrate support part 20 may support the substrate S through vacuum adsorption or mechanical force.

The substrate support part 20 may be provided in a shape corresponding to a shape the substrate S, for example, a circular shape or a rectangular shape. The substrate support part 20 may include a substrate support 22 on which the substrate S is seated and an elevator 24 disposed under the substrate support 22 to elevate the substrate support 22. Here, the substrate support 22 may be manufactured to be larger than the substrate S, and the elevator 24 may be provided to support at least one area of the substrate support 22, for example, a central portion. When the substrate S is seated on the substrate support 22, the substrate support 22 may move to approach the gas injection part 20. Also, a heater (not shown) may be installed in the substrate support 22. The heater generates heat to a predetermined temperature to heat the substrate support 22 and the substrate S seated on the substrate support 22 so that the thin film is uniformly deposited on the substrate S.

At least a portion of the gas supply part 40 may be installed outside the chamber 10 to supply a gas to the gas injection part 30. The gas supply part 40 may include a source gas supply part that supplies a source gas and a reactant gas supply part that supplies a reactant gas. In addition, the gas supply part 40 may further include a purge gas supply part that supplies an inert gas such as an argon (Ar) gas or a low-reactivity gas such as a nitrogen (N₂) gas. In addition, the gas supply part 40 may further include a processing gas supply part that supplies a hydrogen (H₂) gas.

The gas supply part 40 may not necessarily supply one gas to the gas injection part 30, but may be configured to supply a plurality of gases at the same time or to supply a selected gas of the plurality of gases.

The source gas supply part may be configured to supply a gas containing gallium (Ga) as the source gas, and the reactive gas supply part may supply a gas containing nitrogen (N) as the reactive gas. Here, the source gas, that is, the gallium-containing gas, may include a trimethyl gallium (TMGa) gas or a triethyl gallium (TEGa) gas, and the reactive gas, that is, the gas containing nitrogen (N) may include an ammonia (NH₃) gas.

The gas injection part 30 may be disposed at an inner upper side of the chamber 10 to inject the process gas onto the substrate 100. An upper side of the gas injection part 30 may be connected to the gas supply part 40, and a plurality of injection holes (not shown) that spray the process gas onto the substrate S may be defined at a lower side. As described above, a row material gas supply path for spraying and supplying the source gas onto the substrate and a reactant gas supply path for spraying and supplying the reactant gas onto the substrate may be provided inside the gas injection part 30. The source gas supply path 110 and the reactant gas supply path 210 may be provided to be independently separated from each other so that the source gas and the reactant gas are separated from each other without being mixed with each other within the gas injection part 30 and then supplied onto the substrate.

The gas injection part 30 may have a shape corresponding to that of the substrate S, for example, an approximately circular or square shape. Here, the gas injection part 30 may be provided to be spaced a predetermined interval from the sidewall and the cover 14 of the chamber 10. In addition, when generating plasma in the reaction space within the chamber 10, the gas injection part 30 may receive power from the RF power source 50 to act as an upper electrode.

The RF power source 50 may supply power to generate plasma. That is, the RF power source 50 may supply power to generate plasma in the reaction space within the chamber 10. For example, the RF power source 50 may supply the power to either the substrate support part 20 or the gas injection part 30, and the other one of the substrate support part 20 or the gas injection part 30 may be grounded to generate the plasma between the substrate support part 20 and the gas injection part 30.

A semiconductor device in accordance with an exemplary embodiment may be manufactured using the apparatus for processing the substrate described above.

Here, the semiconductor device in accordance with an exemplary embodiment may include a substrate, a crystalline seed layer disposed on the substrate, and a semiconductor layer containing gallium nitride (GaN) and disposed on the seed layer.

The substrate may include various substrates for forming a gallium nitride (GaN) thin film. The substrate may include an amorphous substrate, for example, a glass substrate. The glass substrate may be damaged at a temperature of approximately 600° C. or more, but in an exemplary embodiment, since the thin film is deposited at a temperature of approximately 500° C. or less, the glass substrate having the advantage of being easy to be enlarged in area and be inexpensive may be used.

The seed layer may be disposed on the substrate to form the gallium nitride (GaN) thin film on the seed layer. Here, the seed layer may include a polycrystalline seed layer having a hexagonal crystal structure. When the gallium nitride (GaN) is crystallized into the hexagonal crystal structure, the gallium nitride (GaN) may increase in electron mobility, enable a high-speed operation, and exhibit properties that are resistant to high-temperature heat. As described above, to form the polycrystalline gallium nitride (GaN) thin film, the seed layer for forming the gallium nitride (GaN) thin film may also need to have the same crystal structure. That is, to form the crystalline gallium nitride (GaN) thin film, the seed layer in which a crystal lattice well matches the gallium nitride (GaN) thin film has to be used. Zinc oxide (ZnO) may have a hexagonal crystal structure and be easy to be crystallized even when deposited at a low temperature. Thus, in an exemplary embodiment, the seed layer containing zinc oxide (ZnO) may be used as the seed layer for forming the gallium nitride (GaN) thin film.

The seed layer may be formed using a chemical vapor deposition (CVD) process or an atomic layer deposition (ALD) process. For example, the seed layer may be formed through the atomic layer deposition process. The atomic layer deposition process may form a thin film into a unit of an atomic layer and supply energy, and thus, the crystalline seed layer may be formed more effectively.

The semiconductor layer may contain gallium nitride (GaN) and be formed on the seed layer. To form the gallium nitride (GaN) thin film, in the related art, the semiconductor layer containing gallium nitride (GaN) may be disposed directly on the substrate through a metal organic chemical vapor deposition (MOCVD) method. However, in this case, since the gallium nitride (GaN) thin film is crystallized at a temperature of approximately 1,000° C. or more, there is a limitation in that the glass substrate, which is damaged at a temperature of approximately 600° C. or more, is not used. Thus, in an exemplary embodiment, the crystalline seed layer may be first disposed to crystallize gallium nitride (GaN) at a temperature of approximately 500° C. or less without damaging the glass substrate, and the gallium nitride (GaN) may be disposed on the crystalline seed layer to form a semiconductor layer containing the gallium nitride (GaN).

The semiconductor layer may further include a dopant in addition to the gallium nitride (GaN). The semiconductor layer may need to be formed as a p-type semiconductor layer or an n-type semiconductor layer depending on types of the semiconductor layer. Thus, to form the semiconductor layer as the p-type semiconductor layer, the semiconductor layer may include the gallium nitride (GaN) and the p-type dopant. Here, the p-type dopant may include the group II elements such as zinc (Zn) and magnesium (Mg), or the group VI elements such as oxygen (O), sulfur(S), and phosphorus (P). In addition, to form the semiconductor layer as the n-type semiconductor layer, the semiconductor layer may include the gallium nitride (GaN) and the n-type dopant. Here, the n-type dopant may include the group IV elements such as silicon (Si) or germanium (Ge).

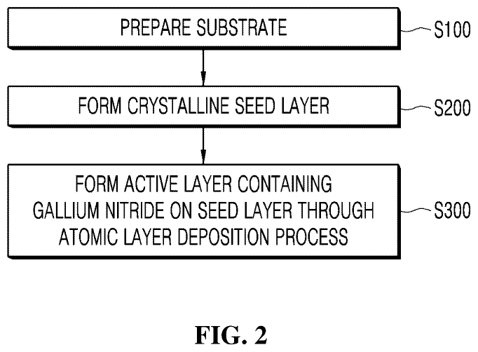

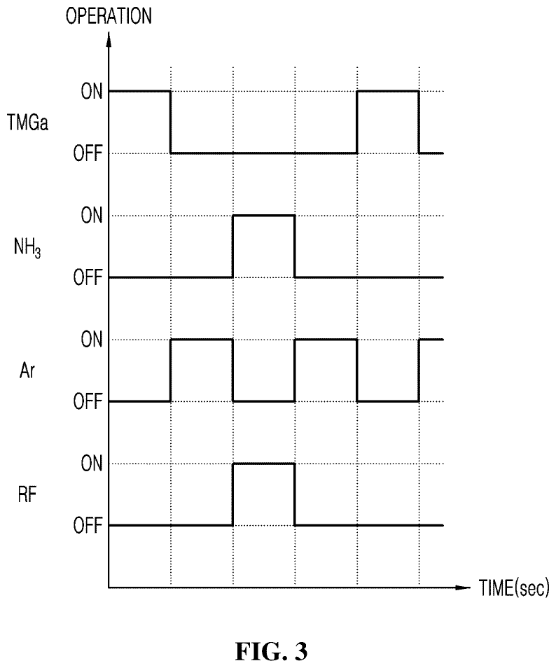

FIG. 2 is a schematic view of a method for manufacturing a semiconductor device in accordance with an exemplary embodiment, and FIG. 3 is a view for explaining a process cycle in a process of forming a semiconductor layer in accordance with an exemplary embodiment.

Referring to FIGS. 2 and 3, a method for manufacturing a semiconductor device in accordance with an embodiment may include a process (S100) of preparing a substrate in a reaction space, a process (S200) of forming a crystalline seed layer on the substrate, and a process (S300) of forming a semiconductor layer containing gallium nitride on the seed layer.

In the process (S100) of preparing the substrate, the substrate may be prepared by loading the substrate into the reaction space of a chamber 10. The substrate loaded into the process space may be seated on a substrate support part 20. Here, as described above, the substrate may include an amorphous substrate for forming a semiconductor layer containing gallium nitride, for example, a glass substrate. In addition, the process (S100) of preparing the substrate may be performed by loading the substrate on which a predetermined functional layer is formed. For example, the process (S100) of preparing the substrate may be performed by loading a substrate on which a gate electrode is formed on a top surface of the substrate, and a gate insulating layer is formed on the substrate and the gate electrode to cover the electrode or performed by loading a substrate on which a source electrode and a drain electrode are spaced apart from each other. Here, the substrate support part 20 may include an electrostatic chuck to adsorb and maintain the substrate S by using electrostatic force so that the substrate S is seated and supported. Alternatively, the substrate support part 20 may support the substrate S through vacuum adsorption or mechanical force.

In the process (S200) of forming the seed layer, the crystalline seed layer is formed on the substrate. Here, the seed layer may include a polycrystalline seed layer having a hexagonal crystal structure. In this case, the seed layer may include zinc oxide (ZnO) in which a crystal lattice well matches a gallium nitride (GaN) thin film.

In the process (S200) of forming the seed layer, the seed layer may be formed on the substrate through a chemical vapor deposition process or an atomic layer deposition process. That is, in the process (S200) of forming the seed layer, the seed layer may be formed through the chemical vapor deposition process in which a source gas containing zinc (Zn) and a reactant gas containing oxygen (O) are supplied at the same time. On the other hand, in the process (S200) of forming the seed layer, the seed layer may be formed through the atomic layer deposition process in which the source gas containing zinc (Zn) and the reactant gas containing oxygen (O) are sequentially supplied. When forming the seed layer containing zinc oxide (ZnO) through the chemical vapor deposition process, the seed layer may be formed to a thickness of approximately 500 Å or more. This is because when forming the seed layer containing zinc oxide (ZnO) through the chemical vapor deposition process, crystals of zinc oxide (ZnO) may be generated at a thickness of approximately 500 Å to approximately 600 Å. On the other hand, when forming the seed layer containing zinc oxide (ZnO) through the atomic layer deposition process, the seed layer may be formed to a thickness of approximately 50 Å or more. This is because the atomic layer deposition process is performed so that a thin film is formed into a unit of an atomic layer to supply energy, and crystals of zinc oxide (ZnO) are relatively quickly generated at a thickness of approximately 50 Å to approximately 100 Å when compared to the chemical vapor deposition process.

On the other hand, the process (S200) of forming the seed layer may include a process of forming a first seed layer on the substrate through the atomic layer deposition process and a process of forming a second seed layer on the first seed layer through the chemical vapor deposition process. As described above, in the process (S200) of forming the seed layer, when the first seed layer is formed through the atomic layer deposition process, and the second seed layer is formed through the chemical vapor deposition process, zinc oxide (ZnO) may be rapidly crystallized, and simultaneously, the seed layer containing zinc oxide (ZnO) may be formed to a sufficient thickness.

Before the process (S300) of forming the semiconductor layer, a process of supplying a gas containing at least one of fluorine (F) or chlorine (Cl) to the reaction space of the chamber 10 may be performed. After forming the seed layer on the substrate, residual materials generated in the process (S200) of forming the seed layer may exist on the seed layer. In addition, to stably form the semiconductor layer on the seed layer, a portion of the formed seed layer may be etched to clean a surface of the seed layer. Thus, in the method for manufacturing the semiconductor device in accordance with an exemplary embodiment, after the process (S200) of forming the seed layer and before the process (S300) of forming the semiconductor layer, a gas containing fluorine (F) may be supplied to the reaction space, a gas containing chlorine (Cl) may be supplied, or a gas containing fluorine (F) and chlorine (Cl) may be supplied to form a high quality semiconductor layer in the subsequent process.

In the process (S300) of forming the semiconductor layer, the semiconductor layer containing gallium nitride (GaN) may be formed on the crystalline seed layer. Here, the semiconductor layer containing gallium nitride (GaN) may form at least a portion of an active layer of a thin film transistor TFT used as a switching circuit in the semiconductor device or display device. For example, the semiconductor layer may form a channel region between the gate electrode, source electrode, and drain electrode of the thin film transistor.

In an exemplary embodiment, the process (S300) of forming the semiconductor layer may be performed in a low temperature process that is performed at a temperature of approximately 500° C. or less. That is, the process (S300) of forming the semiconductor layer may be performed by controlling a temperature of the process space of the chamber 10 to approximately 200° C. or more and approximately 500° C. or less. The semiconductor layer containing gallium nitride (GaN) may be formed at a low temperature of approximately 200° C. to approximately 500° C. through at least one of the chemical vapor deposition process and the atomic layer deposition process, which will be described in more detail below.

In the process (S300) of forming the semiconductor layer, the semiconductor layer containing gallium nitride (GaN) may be formed on the crystalline seed layer through the chemical vapor deposition process or the atomic layer deposition process. On the other hand, the process (S300) of forming the semiconductor layer may include a process of forming a first semiconductor layer on the crystalline seed layer through the atomic layer deposition process and a second process of forming a second semiconductor layer on the first semiconductor layer through the chemical vapor deposition process. As described above, when the first semiconductor layer is formed through the atomic layer deposition process, and the second semiconductor layer is formed through the chemical vapor deposition process, gallium nitride (GaN) may be quickly crystallized on the crystalline seed layer, and simultaneously, the semiconductor layer containing crystalline gallium nitride (GaN) may be formed to a sufficient thickness.

As described above, in the process (S300) of forming the semiconductor layer, at least a portion of the semiconductor layer may be formed through the atomic layer deposition process. In this case, the process (S300) of forming the semiconductor layer may include a process of supplying a source gas containing gallium to the reaction space, a process of purging the reaction space into which the source gas is supplied, a process of supplying a reactant gas containing nitrogen to the reaction space, and a process of purging the reaction space into which the reactant gas is supplied.

In the process of supplying the source gas, the source gas containing gallium is supplied to the substrate. Here, in the process of supplying the source gas, the source gas containing gallium is supplied to the substrate through a source gas supply path of the above-described apparatus for processing the substrate. Here, the source gas containing gallium may include a trimethyl gallium (TMGa) gas or a triethyl gallium (TEGa) gas containing gallium as a main component. In the process of supplying the source gas, the source gas containing gallium is injected and adsorbed onto the substrate.

The process of supplying a dopant gas to the substrate may be performed simultaneously with the process of supplying the source gas or after the process of supplying the source gas. As described above, the semiconductor layer containing gallium nitride (GaN) needs to be formed as a p-type semiconductor layer or an n-type semiconductor layer depending on types thereof. Thus, a process of supplying a p-type dopant gas or a process of supplying an n-type dopant gas to the substrate may be performed simultaneously with or after the process of supplying the source gas. The dopant gas may be supplied through at least one of the source gas supply path or the reactant gas supply path. Here, the p-type dopant gas may be the group II elements such as zinc (Zn) or magnesium (Mg), or the group VI elements such as oxygen (O), sulfur(S), and phosphorus (P), and the n-type dopant gas may be a gas containing the group IV elements such as silicon (Si) and germanium (Ge). As described above, the p-type semiconductor layer or the n-type semiconductor layer may be formed by supplying the p-type dopant gas or the n-type dopant gas at the same time as the process of supplying the source gas or after process of supplying the source gas.

After supplying the source gas, the process of purging the reaction space to which the source gas is supplied may be performed. In the process of purging the reaction space in which the source gas is supplied, the source gas remaining in the reaction space of the chamber 10 may be removed. This may be achieved by supplying an inert gas, for example, an argon (Ar) gas to the reaction space, and the argon (Ar) gas may be supplied through at least one of the source gas supply path or the reactant gas supply path.

After supplying the source gas, a process of forming plasma in the reaction space may be performed. In this case, RF power 50 may be applied in the process of purging the reaction space to form plasma of argon gas (Ar), and the plasma may be formed in the reaction space before or after the process of purging the reaction space. When forming plasma before or after the process of purging the reaction space, a hydrogen (H₂) gas or an oxygen (O₂) gas may be supplied to the reaction space through the above-described processing gas supply part, and the RF power source 50 may be applied. In addition, the argon (Ar) gas may be supplied to the reaction space separately from the purge gas, and the RF power source 50 may be applied. As described above, when the substrate is exposed to the plasma after supplying the source gas, stress of the thin film may be adjusted, and the film quality may be improved.

After the process of purging the reaction space into which the source gas is supplied, the process of supplying the reactant gas may be performed. In the process of supplying the reactant gas, a reactant gas containing nitrogen is supplied onto the substrate. Here, in the process of supplying the reactant gas, the reactant gas containing nitrogen is supplied to the substrate through the reactant gas supply path of the above-described apparatus for processing the substrate. Here, the reactant gas containing nitrogen may include an ammonia (NH₃) gas containing nitrogen as a main component. When the reactant gas is supplied to the substrate on which the source is adsorbed, the source reacts with a reaction material contained in the reactant gas.

Here, in a process (S240) of supplying the reactant gas, the RF power 50 may be applied to the process space so that the reactant gas is activated to generate plasma so as to allow an oxygen (O) component contained in the reactant gas to effectively react with a zinc (Zn) component. That is, when supplying the reactant gas, plasma may be formed in the reaction space of the chamber 10. Here, the process of forming the semiconductor layer may further include a process of applying power to form plasma in the reaction space. Here, at least portion of the process of supplying the reactant gas may be performed while the power for forming the plasma in the reaction space may be applied. That is, at least a portion of a section in which the process of supplying the reactant gas is performed may overlap a section in which the power for forming plasma is applied to the reaction space. In FIG. 3, the RF power 50 is shown to be applied to the reaction space only in the process of supplying the reactant gas. However, the process of applying the RF power 50 to the reaction space may include all the cases in which the RF power 50 is applied while the process of supplying the reactant gas is performed. That is, in the process of applying the RF power 50 to the reaction space, the RF power 50 may be applied before starting the supply of the reactant gas to the reaction space or after terminating the supply of the reactant gas to the reaction space, or the RF power 50 may be applied intermittently, that is, in the form of a pulse while the reactant gas is supplied.

As described above, in the process of supplying the reactant gas, the nitrogen-containing gas supplied by activating and supplying the reactant gas may be activated with nitrogen radicals to react with the gallium component, and a semiconductor layer containing gallium nitride (GaN) may be formed on the substrate at a lower process temperature. That is, when the reactant gas is activated to be supplied to the substrate, the process (S300) of forming the semiconductor layer may be performed by controlling a temperature of the process space of the chamber 10 to a low temperature of approximately 200° C. or more and approximately 500° C. or less.

After the process of supplying the reactant gas, the process of purging the reaction space to which the reactant gas is supplied may be performed. In the process of purging the reaction space in which the reactant gas is supplied, the reactant gas remaining in the reaction space of the chamber 10 may be removed. Like the process of purging the source gas, as described above, the process of purging the reactant gas may be performed by supplying an inert gas, for example, an argon (Ar) gas to the reactant gas, and the argon (Ar) gas may be supplied through at least one of the source gas supply path or the reactant gas supply path.

Here, the process (S300) of forming the semiconductor layer in accordance with an exemplary embodiment may be performed by performing a process cycle including the process of supplying the source gas, the process of purging the source gas, the process of the reactant gas, and the process of purging the reactant gas several times. That is, in the process (S300) of forming the semiconductor layer, the process of supplying the source gas, the process of purging the source gas, the process of the reactant gas, and the process of purging the reactant gas may be performed in one process cycle, and the process cycle may be repeatedly performed until the semiconductor layer containing gallium nitride (GaN) having a desired thickness is formed on the substrate.

The method for manufacturing the semiconductor device in accordance with an exemplary embodiment may further include a process of exposing the semiconductor layer to hydrogen or oxygen plasma after the process (S300) of forming the semiconductor layer. The process of exposing the semiconductor layer to hydrogen or oxygen plasma may be performed, for example, by supplying a hydrogen (H₂) gas or an oxygen (O₂) gas to the reaction space through the above-described processing gas supply part and applying the RF power source 50. Also, in addition to the hydrogen (H₂) gas or oxygen (O₂) gas, an argon (Ar) gas and a helium (He) gas, which are inert gases, may also be used.

When the semiconductor layer is exposed to the hydrogen or oxygen plasma in the process of exposing the semiconductor layer to the hydrogen or oxygen plasma, the semiconductor layer containing amorphous gallium nitride (GaN) may be crystallized. The semiconductor layer may be deposited on the seed layer in an amorphous state. When the semiconductor layer is exposed to the hydrogen or oxygen plasma as in an exemplary embodiment, the semiconductor layer containing amorphous gallium nitride (GaN) may be converted to be crystallized into a single crystal or polycrystalline structure. In addition, if the hydrogen or oxygen plasma is formed in the reaction space to expose the semiconductor layer to the hydrogen or oxygen plasma, stress of the thin film may be adjusted, and impurities remaining in the chamber 10 or impurities contained in the semiconductor layer may be effectively removed.

In the above, the description is made of forming the crystalline seed layer and the semiconductor layer on the substrate in-situ in the same chamber using the above-described substrate processing device, but the exemplary embodiment is not limited thereto. That is, the process of forming the crystalline seed layer on the substrate and the process of forming the semiconductor layer on the crystalline seed layer may be performed continuously in different chambers. In this case, the process of forming the crystalline seed layer may be performed by a sputtering process, and the process of forming the semiconductor layer may be performed by loading the substrate, on which the crystalline seed layer is formed by the sputtering process, into the above-described apparatus for processing the substrate and then performed through the atomic layer deposition. In addition, when the process of forming the crystalline seed layer and the process of forming the semiconductor layer are performed using the chemical vapor deposition or the atomic layer deposition, respective processes may be performed continuously in different chambers.

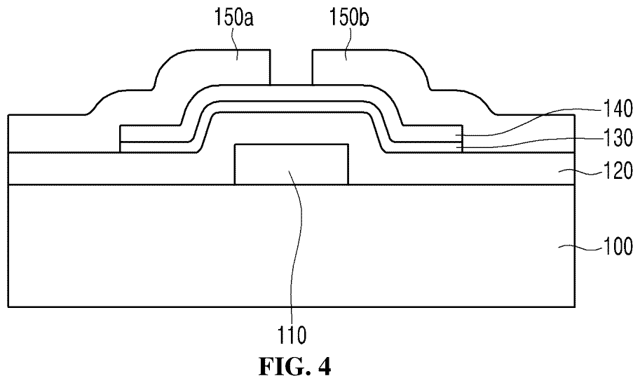

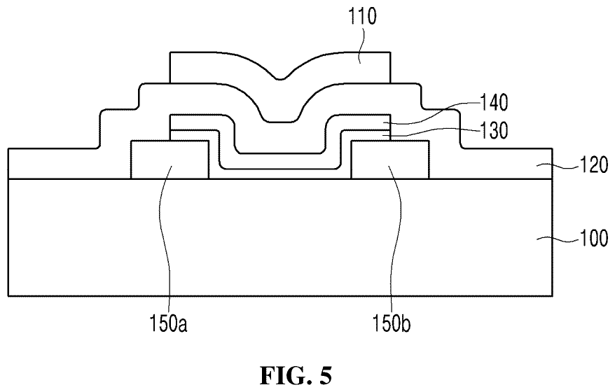

FIG. 4 is a schematic view illustrating a thin film transistor in accordance with an exemplary embodiment, and FIG. 5 is a schematic view illustrating a thin film transistor in accordance with another exemplary embodiment.

Referring to FIG. 4, a thin film transistor in accordance with an exemplary embodiment may be a bottom gate-type thin film transistor and include a gate electrode 110 disposed on a substrate 100, a gate insulating layer 120 disposed on the gate electrode 110, an active layer disposed on the gate insulating layer 120 and including a crystalline seed layer 130 and a semiconductor layer 140 disposed on the seed layer 130, and a source electrode 150a and a drain electrode 150b disposed on the active layer and spaced apart from each other.

As described above, the substrate 100 may include an amorphous substrate, and, for example, may include a glass substrate.

The gate electrode 110 may be made of a conductive material, for example, at least one metal of aluminum (Al), neodymium (Nd), silver (Ag), chromium (Cr), titanium (Ti), tantalum (Ta), molybdenum, or an alloy thereof. In addition, the gate electrode 110 may be formed not only as a single layer but also as a multi-layer including a plurality of metal layers. That is, the gate electrode 110 may be formed as a double layer including a metal layer made of chromium (Cr), titanium (Ti), tantalum (Ta), and molybdenum (Mo), which have excellent physical and chemical properties, and a metal layer made of aluminum (Al) series, silver (Ag) series or copper (Cu) series, which have low specific resistance.

The gate insulating layer 120 is disposed on the gate electrode 110. That is, the gate insulating layer 120 may be disposed on the substrate 100 in addition to upper and side portions of the gate electrode 110. The gate insulating layer 120 may be provided as a thin film using one or more insulating materials of silicon oxide (SiO₂), silicon nitride (SiN), alumina (Al₂O₃), and zirconia (ZrO₂) having excellent adhesion to metal materials and excellent dielectric strength. Here, a high-K dielectric may be a dielectric having a dielectric constant higher than that of silicon oxide (SiO₂) and may include hafnium oxide (HfO₂), zirconium oxide (ZrO₂), etc.

The active layer may be disposed on the gate insulating layer 120, and at least a portion of the active layer may overlap the gate electrode 110. The active layer may include a crystalline seed layer 130 and a semiconductor layer 140 containing gallium nitride. As described above, the active layer may form the seed layer 130 containing crystallized zinc oxide (ZnO) having the hexagonal crystal structure by at least one of the atomic layer deposition process and the chemical vapor deposition process, and the semiconductor layer 140 containing crystallized gallium nitride (GaN) having the hexagonal crystal structure may be disposed on the seed layer 130 using at least one of the atomic layer deposition process or the chemical vapor deposition process.

The source electrode 400 and the drain electrode 500 may be disposed on the active layer, more specifically, on the crystalline semiconductor layer 140 in the active layer and may partially overlap the gate electrode 110 so that the source electrode 150a and the drain electrode 150b are spaced apart from each other with the gate electrode 110 therebetween. The source electrode 150a and the drain electrode 150b may be formed by the same process using the same material and may be made of a conductive material, for example, may be made of at least one metal of aluminum (Al), neodymium (Nd), silver (Ag), chromium (Cr), titanium (Ti), tantalum (Ta), and molybdenum (Mo), or an alloy thereof. That is, the gate electrode 110 may be made of the same material, but may be made of a different material. In addition, each of the source electrode 150a and the drain electrode 150b may be provided as a single layer as well as a multilayer of a plurality of metal layers.

FIG. 5 is a schematic view of a thin film transistor in accordance with another exemplary embodiment. A thin film transistor in accordance with another exemplary embodiment may be a top gate-type thin film transistor and include a source electrode 150a and a drain electrode 150b, which are disposed on a substrate 100 and are spaced apart from each other, an active layer extending on the source electrode 150a and the drain electrode 150b and including a crystalline seed layer 130 and a semiconductor layer 140 disposed on the seed layer 130, a gate insulating layer 120 disposed on the active layer, and a gate electrode 110 disposed on the gate insulating layer 120.

Even in the case of the bottom gate-type thin film transistor, contents in relation to the thin film transistor of FIG. 4 may be applied as they are. That is, in the case of the thin film transistor in accordance with another exemplary embodiment, the active layer may be disposed on the source electrode 150a and the drain electrode 150b so as to be connected by a portion disposed on an area, on which the substrate 100 is exposed, between the source electrode 150a and the drain electrode 150b and include a crystalline seed layer 130 and a semiconductor layer 140 containing gallium nitride and disposed on the seed layer 130. As described above, the active layer may form the seed layer 130 containing crystallized zinc oxide (ZnO) having the hexagonal crystal structure by at least one of the atomic layer deposition process and the chemical vapor deposition process, and the semiconductor layer 140 containing crystallized gallium nitride (GaN) having the hexagonal crystal structure may be disposed on the seed layer 130 using at least one of the atomic layer deposition process or the chemical vapor deposition process. As described above, even in the case of the thin film transistor in accordance with another exemplary embodiment, the contents described in the thin film transistor in accordance with the foregoing exemplary embodiment may be applied as they are except for a stacking order, and thus, duplicated descriptions will be omitted.

As described, the semiconductor layer containing gallium nitride crystallized at the low temperature may be formed.

That is, in accordance with the embodiments of the present disclosure, the semiconductor layer may be formed on the crystalline seed layer to form the semiconductor layer containing gallium nitride crystallized at the low temperature of approximately 500° C. or less without damaging the glass substrate.

In addition, the semiconductor layer formed described above may be used as the active layer to manufacture the transistor that is enables the fast signal conversion and has the low energy loss rate.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications in accordance with the exemplary embodiments of the present invention may belong to the technical spirit of the present invention.

1. A semiconductor device comprising:
a glass substrate;
a seed layer disposed on the glass substrate; and
a semiconductor layer containing gallium nitride and disposed on the seed layer.

2. The semiconductor device of claim 1, wherein the seed layer has a hexagonal crystal structure.

3. The semiconductor device of claim 2, wherein the seed layer comprises zinc oxide.

4. The semiconductor device of claim 1, wherein the seed layer is formed through an atomic layer deposition process.

5. A method for manufacturing a semiconductor device, the method comprising:
preparing a glass substrate in a reaction space;
forming a crystalline seed layer on the glass substrate; and
forming a semiconductor layer containing gallium nitride on the seed layer.

6. The method of claim 5, wherein the seed layer contains zinc oxide, and in the forming of the seed layer, the seed layer is formed on the glass substrate through an atomic layer deposition process.

7. The method of claim 5, wherein, in the forming of the semiconductor layer, the semiconductor layer is formed on the seed layer through a chemical vapor deposition process or an atomic layer deposition process.

8. The method of claim 5, wherein the forming of the semiconductor layer comprises:
forming a first semiconductor layer on the seed layer through an atomic layer deposition process; and
forming a second semiconductor layer on the first semiconductor layer through a chemical vapor deposition process.

9. The method of claim 5, wherein, in the forming of the semiconductor layer,
the semiconductor layer is formed through an atomic layer deposition process in which a source gas containing gallium and a reactant gas containing nitrogen are sequentially supplied to the reaction space, and
when the reactant gas is supplied, plasma is formed in the reaction space.

10. The method of claim 5, wherein, in the forming of the semiconductor layer,
the semiconductor layer is formed through an atomic layer deposition process in which a source gas containing gallium and a reactant gas containing nitrogen are sequentially supplied to the reaction space, and
before supplying the reactant gas after supplying the source gas, plasma is formed in the reaction space.

11. The method of claim 5, wherein, in the forming of the seed layer and the forming of the semiconductor layer, a temperature of the reaction space is maintained to a temperature of approximately 500° C. or less.

12. The method of claim 5, further comprising exposing the semiconductor layer to hydrogen or oxygen plasma.

13. The method of claim 5, further comprising, before the forming of the semiconductor layer, supplying a gas comprising at least one of fluorine or chlorine to the reaction space.

14. The method of claim 5, wherein the forming of the seed layer and the forming of the semiconductor layer are performed in the same chamber.

15. The method of claim 5, wherein the forming of the seed layer and the forming of the semiconductor layer are continuously performed in chambers different from each other.

16. A thin film transistor comprises:
a gate electrode disposed on a glass substrate;
a gate insulating layer disposed on the gate electrode;
an active layer disposed on the gate insulating layer, comprising a crystalline seed layer and a semiconductor layer containing gallium nitride and disposed on the seed layer; and
a source electrode and a drain electrode spaced apart from each other on the active layer.

17. A thin film transistor comprising:
a source electrode and a drain electrode spaced apart from each other on a glass substrate;
an active layer extending on the source electrode and the drain electrode and comprising a crystalline seed layer and a semiconductor layer containing gallium nitride and disposed on the seed layer;
a gate insulating layer disposed on the active layer; and
a gate electrode disposed on the gate insulating layer.

18. The thin film transistor of claim 16, wherein the seed layer has a hexagonal crystal structure.

19. The thin film transistor of claim 18, wherein the seed layer comprises zinc oxide.

20. The thin film transistor of claim 17, wherein the seed layer has a hexagonal crystal structure.
